(19) United States
(12) Patent Application Publication
(10) Pub. No.: US 2026/0271213 A1
(43) Pub. Date: Sep. 10, 2026

(54) Switch Having Vertical Line Card

(71) Applicant: Eridu AI Corporation, Saratoga, CA (US)

(72) Inventors: Christopher Robert Cole, Saratoga, CA (US); Frank Yang, Saratoga, CA (US)

(21) Appl. No.: 19/075,403

(22) Filed: Mar. 10, 2025

(51) Int. Cl. H05K 7/14; G06F 1/18

(52) U.S. Cl. CPC H05K 7/1452; G06F 1/183; H05K 7/1447

(57) ABSTRACT

An apparatus, such as a switch, is provided that comprises, in one example, a housing that includes a plurality of module cages that receive optical and/or transceiver interface modules. In a further example, the cages are provided in sub-assembly enclosures, which may also include connectors and cable bundles that constitute part of electrical connection to a processor, such as a switch ASIC, provided on a vertical line card within the housing. Thus, in the event of a fault or defect in one or more of the fiber bundles or other defective component, only the sub-assembly enclosure including the defective fiber bundle or component need be replaced, such that there is no need to disable the entire switch. Accordingly, a more efficient repair may be made compared to a switch in which the cables are not so modularized. Alternatively, the cages and interface modules may be provided outside the sub-assembly enclosures.

### BACKGROUND

The document describes switching systems configured to receive optical and electrical modules.

### SUMMARY

An apparatus, such as a switch, is provided that comprises, in one example, a housing that includes a plurality of module cages that receive optical and/or transceiver interface modules. In a further example, the cages are provided in sub-assembly enclosures, which may also include connectors and cable bundles that constitute part of electrical connection to a processor, such as a switch ASIC, provided on a vertical line card within the housing. Thus, in the event of a fault or defect in one or more of the fiber bundles or other defective component, only the sub-assembly enclosure including the defective fiber bundle or component need be replaced, such that there is no need to disable the entire switch. Accordingly, a more efficient repair may be made compared to a switch in which the cables are not so modularized. Alternatively, the cages and interface modules may be provided outside the sub-assembly enclosures.

### BRIEF DESCRIPTION OF THE DRAWINGS

FIG. 1 depicts an exemplary system configured for data processing and optical and/or electrical communication within a data center environment, accordance with some embodiments of the present disclosure;

FIG. 2A shows a simplified perspective view of a switch consistent with an aspect of the present disclosure;

FIG. 2B shows a high-level perspective view of internal components of the switch shown in FIG. 2A consistent with a further aspect of the present disclosure;

FIG. 3 shows a front view of a switch consistent with additional aspects of the present disclosure;

FIGS. 4A and 4B show examples of cross-sectional or side views of internal components of the switch shown in FIG. 3;

FIG. 5 shows a front view of a switch consistent with a further aspect of the present disclosure;

FIGS. 6A and 6B show cross-sectional or side views of example arrangements of internal components of the switch shown in FIG. 5;

FIGS. 7 and 8 show additional cross-sectional or side views of example arrangements of internal components of the switch shown in FIG. 5;

FIGS. 9A and 9B show further examples of cross-sectional or side views of internal components of the switch shown in FIG. 3;

FIGS. 10A and 10B show further cross-sectional or side views of example arrangements of internal components of the switch shown in FIG. 5; and

FIGS. 11 and 12 show additional cross-sectional or side views of example arrangements of internal components of the switch shown in FIG. 5.

### DETAILED DESCRIPTION

The following detailed description of example implementations refers to the accompanying drawings. The same reference numbers in different drawings may identify the same or similar elements.

Communication networks, such as those provided in data centers often include switches for directing data between various processing units, such as CPUs, GPUs, and further interconnected switches. These switches often include optical or electrical transceiver modules and electrical processing components, such as a switch application specific integrated circuit (ASIC) provided in a chassis. As increasing numbers of processing units are provided in a data center, for example, higher capacity switches may be required that can accommodate a large number of transceiver modules. However, such switches require greater connectivity, higher component density, and thermal management. Moreover, manufacturing or assembling high-capacity switches, as well as repairing or sparing components in such switches, may be difficult in light of such requirements.

As noted above and described in greater detail below, an apparatus, such as a switch, is provided that comprises, in one example, a housing that includes a plurality of module cages that receive optical and/or transceiver interface modules. In a further example, the cages are provided in sub-assembly enclosures, which may also include connectors and cable bundles that constitute part of electrical connection to a processor, such as a switch ASIC, provided on a vertical line card within the housing. Thus, in the event of a fault or defect in one or more of the fiber bundles or other defective component, only the sub-assembly enclosure including the defective fiber bundle or component need be replaced, such that there is no need to disable the entire switch. Accordingly, a more efficient repair may be made compared to a switch in which the cables are not so modularized. Alternatively, the cages and interface modules may be provided outside the sub-assembly enclosures.

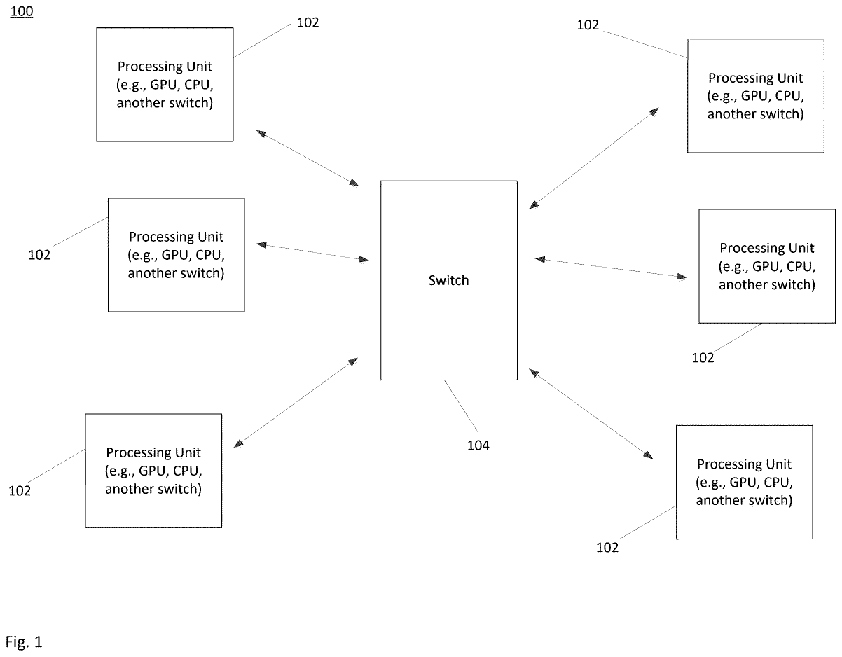

Turning to the drawings, FIG. 1 depicts a system 100 configured for data processing and optical and/or electrical communication within a data center environment, for example. The system 100 comprises a plurality of processing units 102 interconnected to a switch 104 consistent with the present disclosure. Each processing unit 102 may include a graphics processing unit (GPU), a central processing unit (CPU), or alternatively operate as another switch. In the illustrated architecture, switch 104 is operable to receive data transmissions from one or more of the processing units 102 and to direct this data accordingly to one or more of the other processing units 102.

FIG. 1 is provided as an example of a system. Other examples may differ from what is described with regard to FIG. 1. The number and arrangement of components shown in FIG. 1 are provided as an example. In practice, there may be additional components, fewer components, different components, or differently arranged components than those shown in FIG. 1.

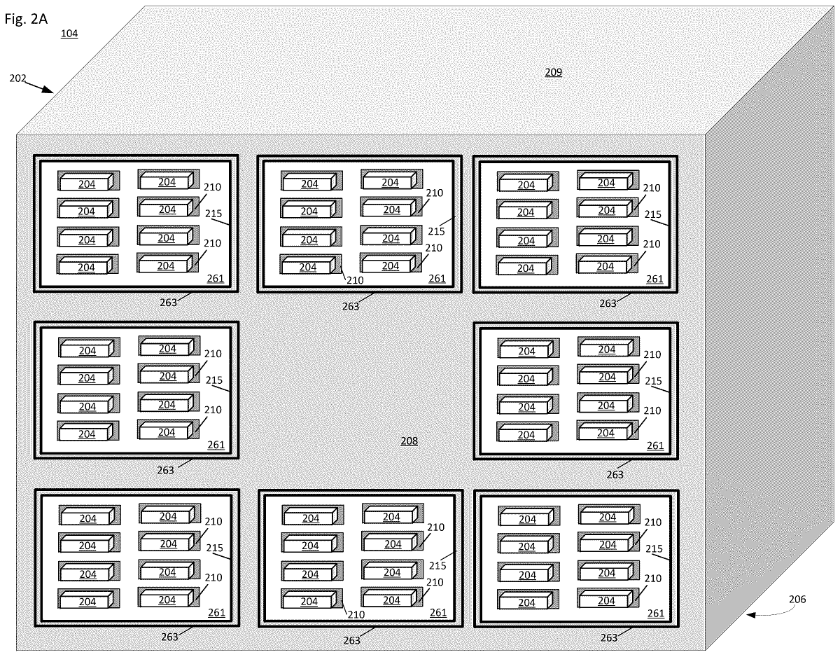

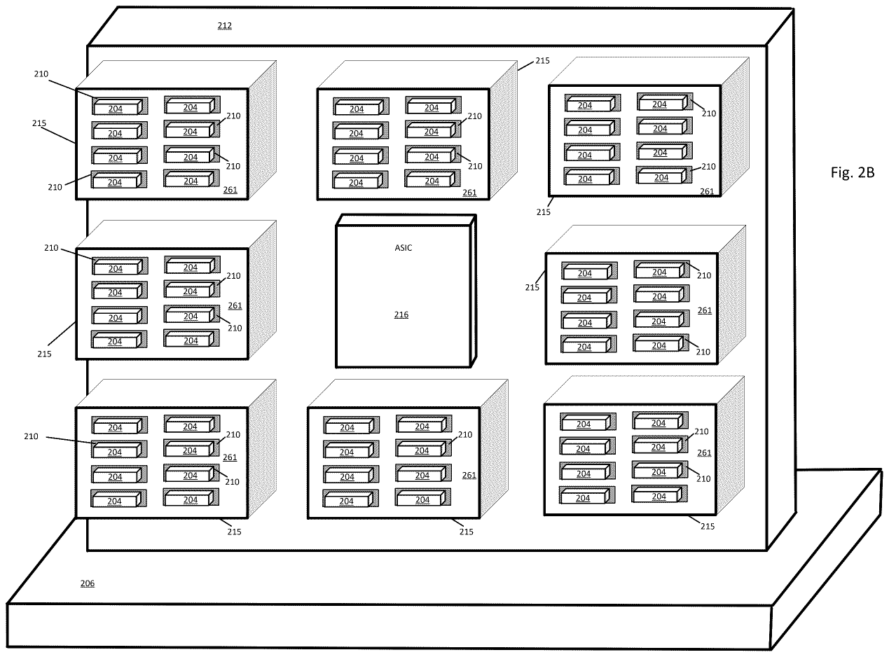

FIG. 2A shows switch 104 in greater detail. As shown in FIG. 2A, switch 104 includes a housing or chassis 202 that comprises a bottom 206 and a top 209. The housing 202 additionally features a front panel 208 which includes a plurality of module slots or ports 210.

Each module slot 210 is configured to receive a corresponding optical or electrical module or interface module 204, which in one example is a transceiver module. These modules or interface modules 204 facilitate communication between switch 104 and processing units 102 (not shown in this figure). Modules 204 supporting optical communication are operable to convert input optical signals into input electrical signals for processing or switching and converting processed or switched electrical signals into output optical signals. Each module may be a pluggable module, such as a module complying with an OSFP standard or OSFP module.

Put another way, modules 204 may be embodied as transceiver modules, capable of both outputting optical signals carrying data to at least one of the processing units 102 and receiving optical signals carrying data from at least one of the processing units 102. In this particular embodiment, modules 204 are shown as being provided in module slots 210 in faceplate 261 of sub-assembly enclosure 215. Sub-assembly enclosure 215, in turn, may be provided in openings 263 of chassis or housing front panel 208. In a further example, modules 204 may be transceiver modules that output or transmit first electrical signals as well as receive second electrical signals.

The housing 202 is designed with structural features to support the integration of modules 204, ensuring their alignment and secure attachment within the module slots 210 and providing protection for internal components. Although not specifically illustrated in FIG. 2A, the housing 202 may contain additional components, such as data processors and circuits, which interact with modules 204 to perform necessary communication and signal conversion functions.

As indicated above, FIG. 2A is provided as an example. Other examples may differ from what is described with regard to FIG. 2A.

FIG. 2B shows a simplified perspective view of components provided within switch 104. Namely, FIG. 2B shows a vertical host card 212, also referred to as a vertical line card, designed to operate within the switch 104.

The vertical host card 212 supports a processor, such as an application-specific integrated circuit (ASIC) 216, mounted on vertical line card 212 and facing front panel 208 of the chassis 202. The ASIC 216 may provide specialized processing operations, such as switching, required for routing or directing data through switch 104. While FIG. 2B illustrates the ASIC 216 positioned on the side of the vertical host card 212 that faces the front panel 208, it is contemplated that the ASIC 216 could alternatively be positioned on the reverse side, facing away from the front panel 208 towards the back of the chassis 202.

In the arrangement shown in FIG. 2B, multiple sub-assembly enclosures 215 are connected or attached to vertical line card 212. As discussed in greater detail below, each sub-assembly enclosure 215 includes two vertical mezzanine cards and associated cables and connectors (not shown in FIG. 2B for ease of illustration). In addition, each sub-assembly enclosure is detachable from vertical line card 212 independently of the other sub-assembly enclosures 215. As a result, in the event one of the sub-assembly enclosures 215 includes a faulty component, such as a defective mezzanine card or broken or faulty cable, only that sub-assembly enclosure 215 may be readily detached from line card 212 while the remaining sub-assembly enclosures remain in place and operational. Accordingly, defective components may be readily replaced or repaired by only removing the corresponding sub-assembly enclosure.

As further shown in FIG. 2B, the bottom of the housing 206 provides a structural base for securely positioning the vertical host card 212 and the associated components within housing 202. The arrangement of vertical host card 212, ASIC 216 mounted thereon, and sub-assembly enclosures 215 with interface modules 204 represents an example configuration that facilitates effective communication between the modules 204 and the processing unit within the switch via ASIC 216.

Alternate configurations with varying numbers and arrangements of mezzanine cards, host cards, connectors, and modules are also considered to fall within the scope of the present disclosure.

FIG. 2B is provided as an example. Other examples may differ from what is described with regard to FIG. 2B. The number and arrangement of components shown in FIG. 2B are provided as an example. In practice, there may be additional components, fewer components, different components, or differently arranged components than those shown in FIG. 2B.

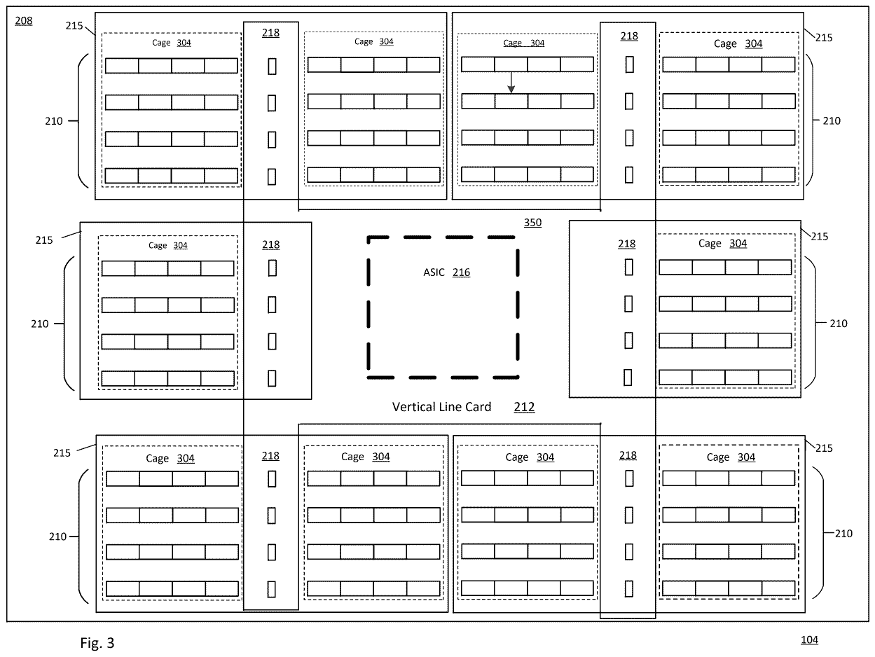

As further shown in FIG. 3, the configuration of sub-assembly enclosures 215 is such that peripheral portions thereof do not overlap with the switch ASIC 216 on the vertical line card 212 when viewed from the front of chassis 202. As a result, ASIC 216 may be more readily accessed. Moreover, greater airflow may be directed over ASIC 216 to facilitate more efficient cooling. Accordingly, as shown in FIG. 3, gap 350 is shown over ASIC 216. Additionally, the arrangement of each sub-assembly enclosure 215 in FIG. 3 includes cages 304, which serve to protect and organize the optical or electrical modules 204. Cages 304 are typically constructed to provide a stable structure for module insertion and retention, as well as aiding in thermal management and electromagnetic interference (EMI) shielding.

In addition to the advantages noted above in providing a modular assembly based on such sub-assembly enclosures, it is noted that, in one example, the sub-assembly enclosures may be manufactured separately from line card 212 and associated components may be readily plugged into connectors attached to the line card to complete switch 104.

Optical modules 204 may include optical transceiver modules compliant with an OSFP standard. The modules or interface modules may be pluggable, such as into a connector as described below. In a further example, 160 modules are provided, each with a capacity of 800 Gb/s to thereby support a total interconnect bandwidth of 128 Tb/s. Other numbers of module slots 210 and modules, as well as module bandwidths result in different interconnect bandwidths. The optical modules 204 are grouped in 4×4 two-dimensional array in cages 304, in the example shown in FIG. 3. Other cage groupings and other cage array sizes, such as 8×4 two-dimensional array are contemplated herein. Moreover, the example shown in FIG. 3 includes six sub-assembly enclosures 215 and associated cages 304 in which the optical modules 204 are provided or inserted. Further, in the example shown in FIG. 3, only ASIC 216 is provided on vertical line card (VLC) 212 and other support circuitry are located, but no optical modules.

Vertical line card 212 can include printed circuit boards (PCBs), organic substrates or other material types used for assembling and interconnecting electrical components, such as ASICs. It is understood that a greater or lower number of module slots other than that shown in FIG. 3A can be supported.

As indicated above, FIG. 3 is provided as an example. Other examples may differ from what is described with regard to FIG. 3. The number and arrangement of components shown in FIG. 3 are provided as an example. In practice, there may be additional components, fewer components, different components, or differently arranged components than those shown in FIG. 3.

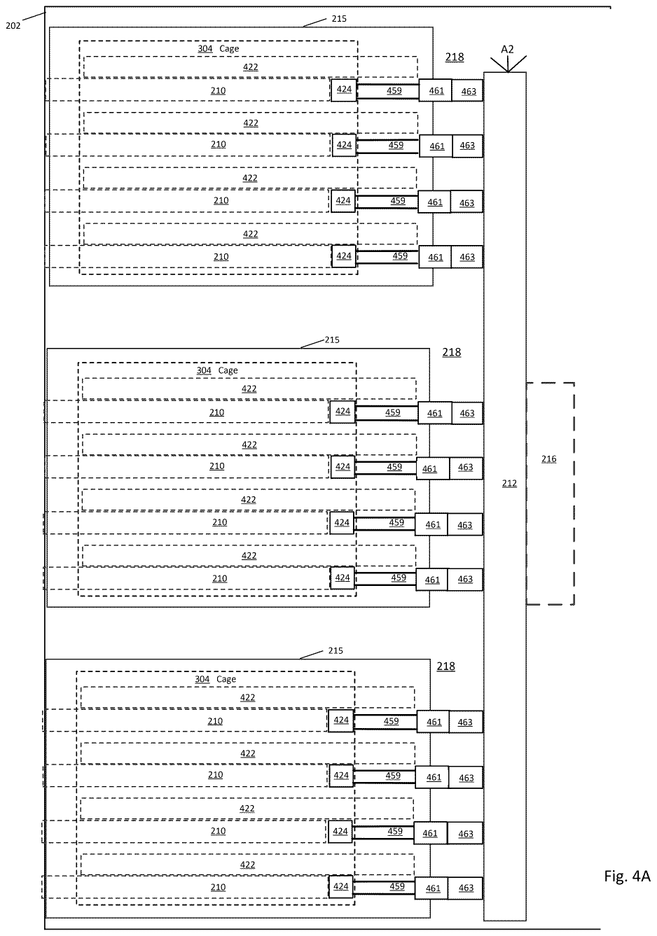

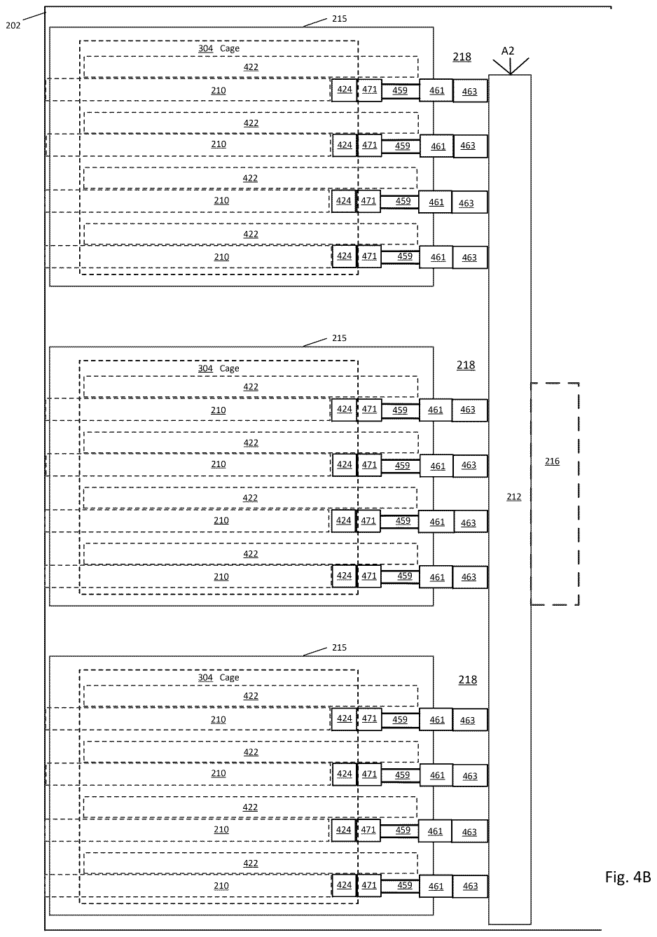

FIG. 4A shows a cross-sectional or side view of internal components of switch 104 shown in FIG. 3. In particular, the example shown in FIG. 4A includes an arrangement of sub-assembly enclosures in proximity to a vertical line card (VLC) 212 for optimizing signal integrity and thermal management in switch 104.

As noted above, each of sub-assembly enclosures 215 houses a plurality of optical or electrical modules contained within module slots or ports 210 of cages 304. These modules, though not explicitly labeled, are understood to be housed within each sub-assembly enclosure 215.

FIG. 4A shows connections between ASIC 216 and module slots 210 using both cables and connectors. Other components are contemplated herein. In the example shown in FIG. 4A, ASIC 216 is provided on one side of vertical line card 212 and two-piece connectors including connectors 461 and 463 are provided on the opposite side of line card 212. The two-piece connectors are arranged or provided groups of relatively small connectors 218 (also shown in FIG. 3) that receive electrical signals from and supply electrical signal to ASIC 216 via conductors embedded in card 212. Thus, electrical signals output from ASIC 216 are provided to the two-piece connectors including connectors 461 and 463 and next fed to corresponding cable bundles 459, which supply the electrical signals to a further connector 424, which, in one example, is a receptacle connector operable to receive and electrically connect to an interface module 204 when such module is plugged into slot 210.

It is noted that, instead of a two-piece connector, other connectors including, interposers, for example, may be provided. In one example, cables 459 carry high speed signals from ASIC 216, as well as power and control signals from ASIC 216. Thus, in the example shown in FIG. 4A, direct connections are made to interface modules via connectors 424 and to line card 212 via two-piece connectors 461/463 without any intervening connections using a mezzanine card, for example.

As further shown in FIG. 4A, heat transfer elements 422, which may include one of a cold plate, an air-cooled heat sink, or a liquid cooled cold plate are provided to remove heat from modules 204 when such modules are provided in module cages 304. Further, as noted above, receptacle connector 424 may be provided to receive and provide an electrical connection to each module when inserted into a slot 210.

Returning to FIG. 3, the two-piece connector including pieces or portions 461 and 463 may constitute a low-profile two-piece connector in one example. As a result, a relatively high signal integrity may be obtained. In a further example, no vertical line card or portion thereof is located in front of ASIC 216 to thereby prevent interference.

As noted above, modules 204 may be cooled by heat transfer elements, such as heat sinks or cold plates. If heat sinks are provided, air flow is preferably directed over the heat sinks. As a result, heat generated by modules 204, when such modules are provided in cages 304, and absorbed by the heat sinks is dissipated by the air flow, thereby cooling the heat sinks. Preferably, the heat sinks are mounted to the top of and are thus in contact with modules 204, and the air flow is through holes in sub-assembly enclosures 215, similar through holes may also be provided in vertical line card 212. Modules 204 can also be cooled by a cold plate, which may also extend through holes in the vertical mezzanine card 214 with heat extracted behind such card by way of a liquid coolant, for example.

As noted above, housing 202 includes vertical host or line card 212, which, in one example, is oriented at an angle A2 relative to the front panel 208, the angle being in a range from −60° to 60°, as shown in FIG. 4A. In a further example, angle A2 is 0°, such that card 212 is parallel to front panel 208. Line cards discussed below may also be oriented within a range of −60° to 60° relative to front panel 208 in a manner similar to that discussed above in connection with FIG. 4A.

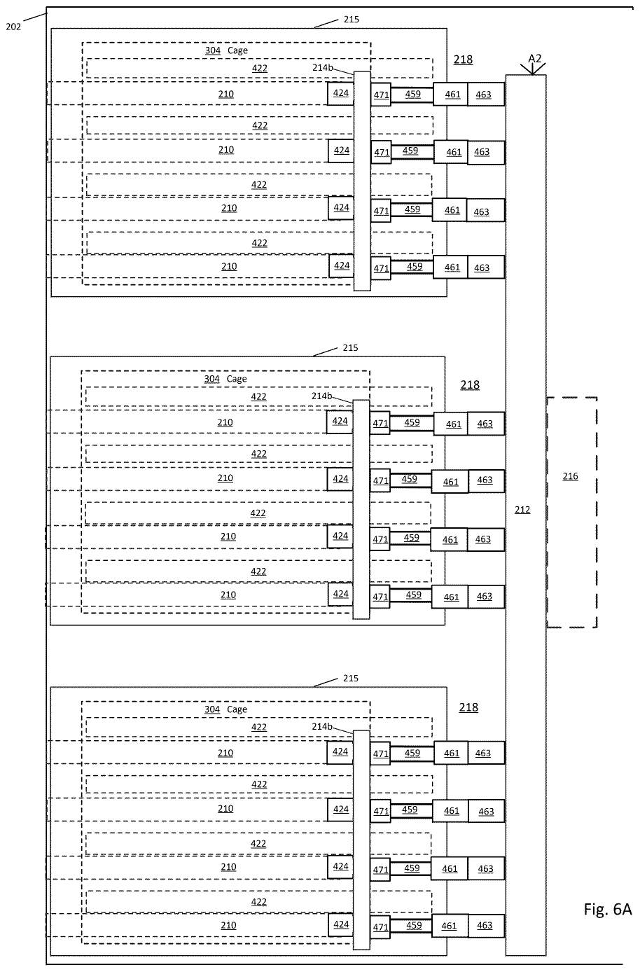

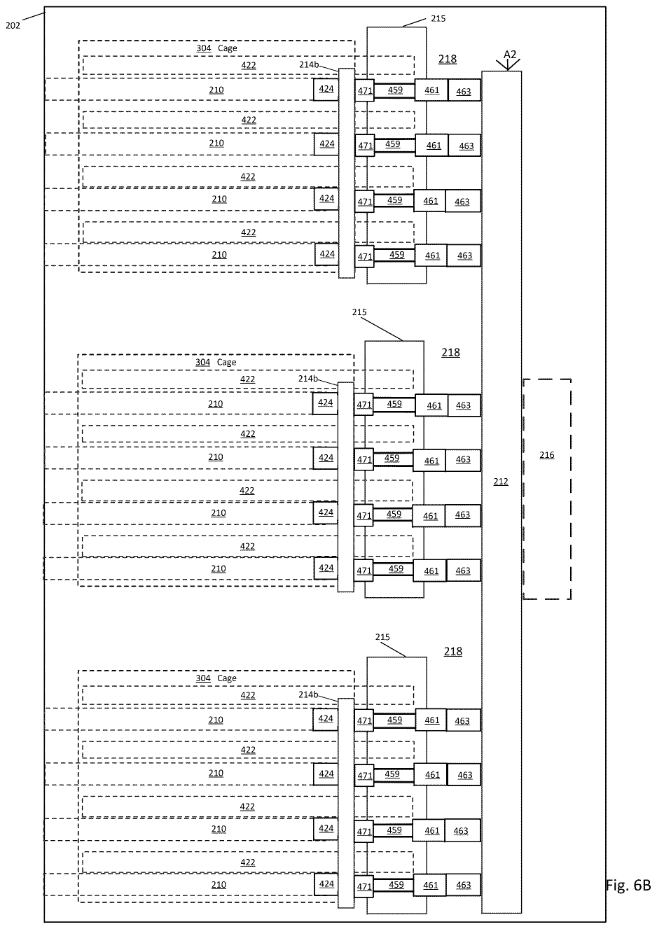

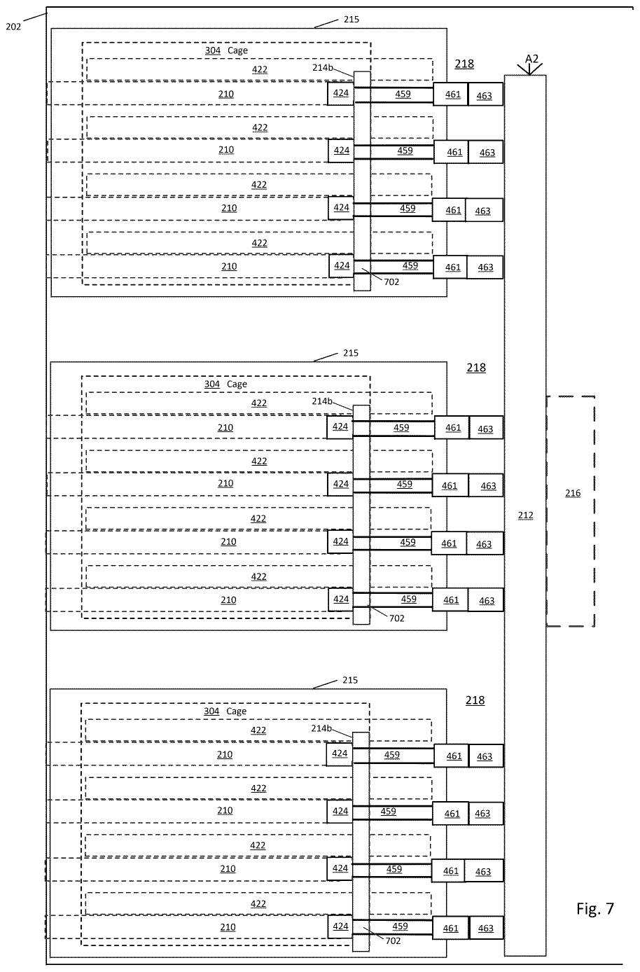

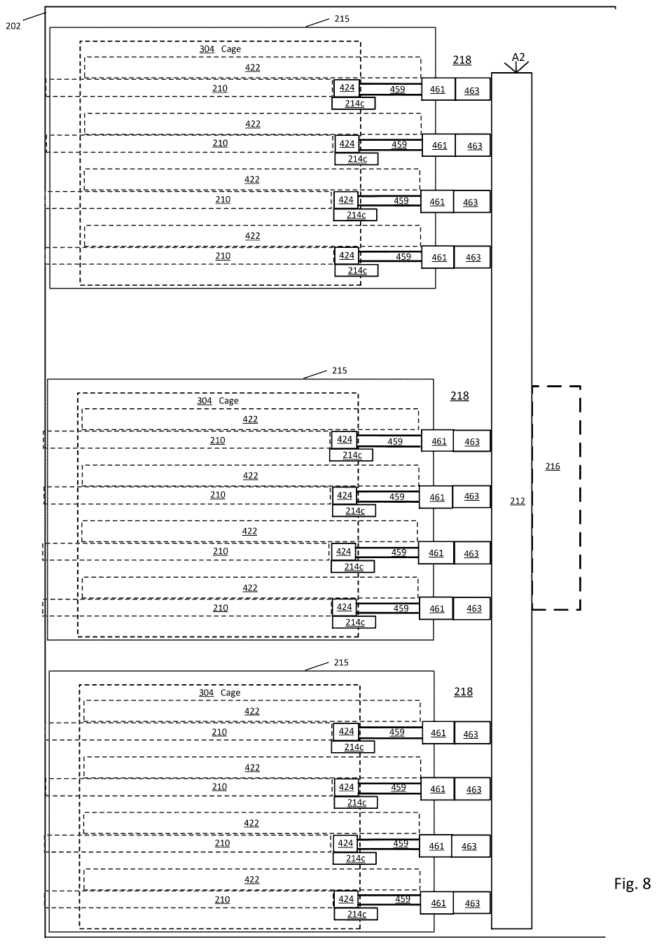

In one example, an electrical connections may be provided between connectors 424 and line card 212. Each such connection may include a corresponding one of connectors 424, cable bundles 459, two piece connectors 461/463. As discussed in greater detail below, the electrical connection may further include a corresponding one of connectors 471 (FIGS. 4B, 6A, and 6B) connecting or coupling connectors 424 to cable bundles 459, conductors 702 extending through mezzanine cards 214b (FIG. 7) connecting connectors 424 to cable bundles 459, and conductors provided on horizontal mezzanine cards 214c connecting connectors 424 to cable bundles 459 (FIG. 8). At least part of each electrical connection may be provided in an associated one of sub-assembly enclosures 215.

It is understood that the vertical mezzanine cards 214b discussed below in connection with FIGS. 6A, 6B, and 7 may similarly be oriented at an angle in the range noted above in connection with line card 212.

FIG. 4B is provided as an example. Other examples may differ from what is described with regard to FIG. 4B, such as in the number of components shown therein.

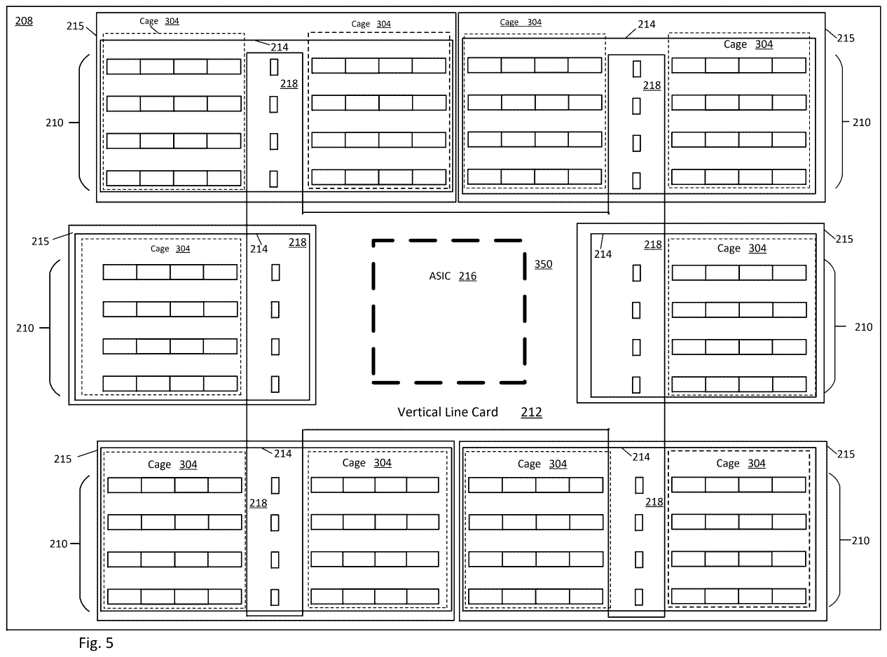

FIG. 5 shows a front view of a switch consistent with a further aspect of the present disclosure. Namely, the example shown in FIG. 5 is similar to that shown in FIG. 3. In FIG. 5, however, a plurality of vertical mezzanine cards 214 is shown, each of which is provided in a respective one of the plurality of sub-assembly enclosures 215. In addition, card 214 is shown entirely overlapping a respective one of cages 304 when viewed from the front of housing 202. It is understood that greater or fewer module slots can be supported than that shown in FIG. 5.

FIG. 6A shows a cross-sectional or side view of an example of an arrangement of components within the switch shown in FIG. 5. The components are similar to those shown in FIGS. 4A and 4B. For example, heat transfer elements 422 and receptacle connectors 424 are shown in FIGS. 4A and 4B, as well as FIG. 6A. In addition, FIG. 6A shows vertical mezzanine card 214b. Moreover, connectors 471 are provided that connect to cables 459. Connectors 471 are provided on one side of vertical mezzanine card 214b and the receptacle connectors that connect to modules 204 are provided on the other (opposite) side of vertical mezzanine card 214b. Here, conductors are included or embedded in mezzanine card 214b to electrically connect connectors 471 to connectors 421 and the modules. Thus, in FIG. 6A, electrical signals are transmitted from cables 459 to connectors 424 via connectors 471 and the embedded conductors in mezzanine card 214b. In one example, power and control signals are provided by vertical mezzanine cards 814b.

It is noted that in each of the examples disclosed herein, electrical signal flow from modules 204 to ASIC 216 is in the reverse direction as that described above, but otherwise such signal flow is through the components noted above that carry electrical signal from ASIC 216 to modules 204.

FIG. 6B shows an example of an arrangement of components similar to that shown in FIG. 6a. In FIG. 6b, however, sub-assembly enclosures 215 do not include cages 304. Further, in the example shown in FIG. 6B, each of connectors 471 may include a two-piece connector. Consistent with a further aspect of the present disclosure, part of each electrical connection between connectors 424 and line card 212 in the examples disclosed herein, such as in each of the FIGS. 4, 6a, 6b, 7, and 8, may be included in a sub-assembly enclosure. Namely, in one example shown in FIG. 6b, each sub-assembly enclosure 215 may include electrical connections comprising a corresponding group of connectors 471, group of cable bundles 459, group of connectors 461, a respective one of mezzanine cards 214b, and connector 463. Further, in the example shown in FIG. 6B, mezzanine cards 214b, cages 304, and connectors 424 are provided outside each sub-assembly enclosure 215. In the example shown in FIGS. 4A and 4B, each group of connectors 424 associated with a corresponding module cage 304 is provided, along with the cage in a respective sub-assembly enclosure 215, and, in the examples shown in FIGS. 6A, 7, and 8, each sub-assembly enclosure further includes mezzanine cards 214b (FIGS. 6A and 7) or horizontal mezzanine card 214c (FIG. 8). Thus, in a further example, each sub-assembly enclosure may include one or more of connectors 424, mezzanine cards 214b, and 214c, connectors 471, cable bundles 459, connectors 461, and connectors 463, as well as part of electrical connections including each of these components or elements.

FIG. 7 shows a cross-section or side view of another example of switch 104. The example shown in FIG. 7 is similar to that shown in FIGS. 6A and 6B. In FIG. 7, however, connectors 471 are omitted and cable bundles 459 are connected to connectors 424 by way of conductors 702 included in vertical mezzanine cards 214b. In a further example, a separate direct connection is provided to second vertical mezzanine cards 214b to supply power and control signals.

FIG. 8 shows a cross-section or side view of another example of switch 104. The example shown in FIG. 8 is similar to that shown in FIG. 4A. In FIG. 8, however, connectors 424 are provided on horizontal mezzanine cards 214c, which, in one example, extend parallel to bottom 206 of housing 202. In a further example, there is a direct connection for power and control to horizontal mezzanine cards 214c.

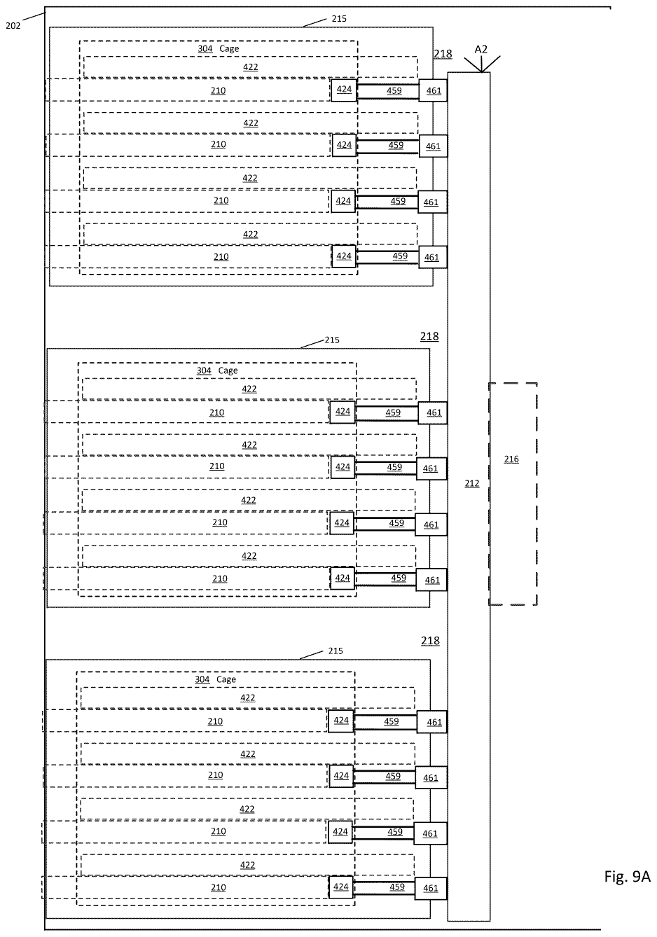

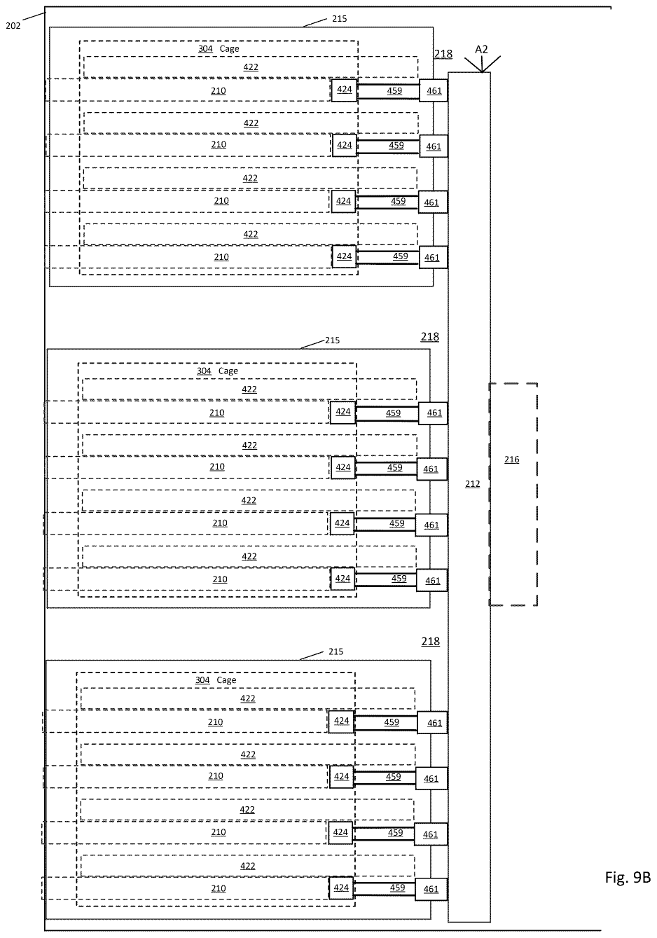

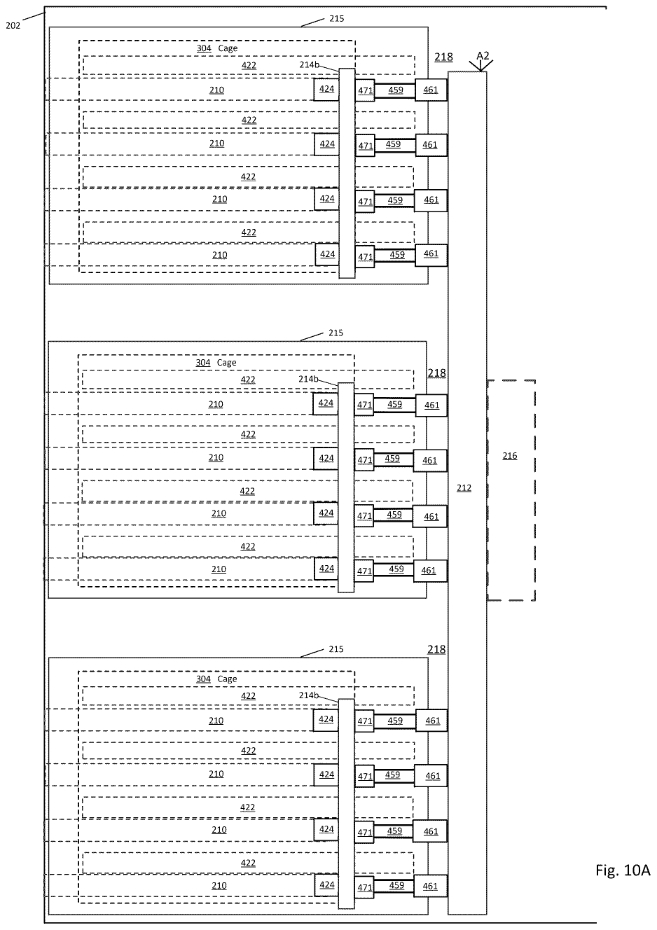

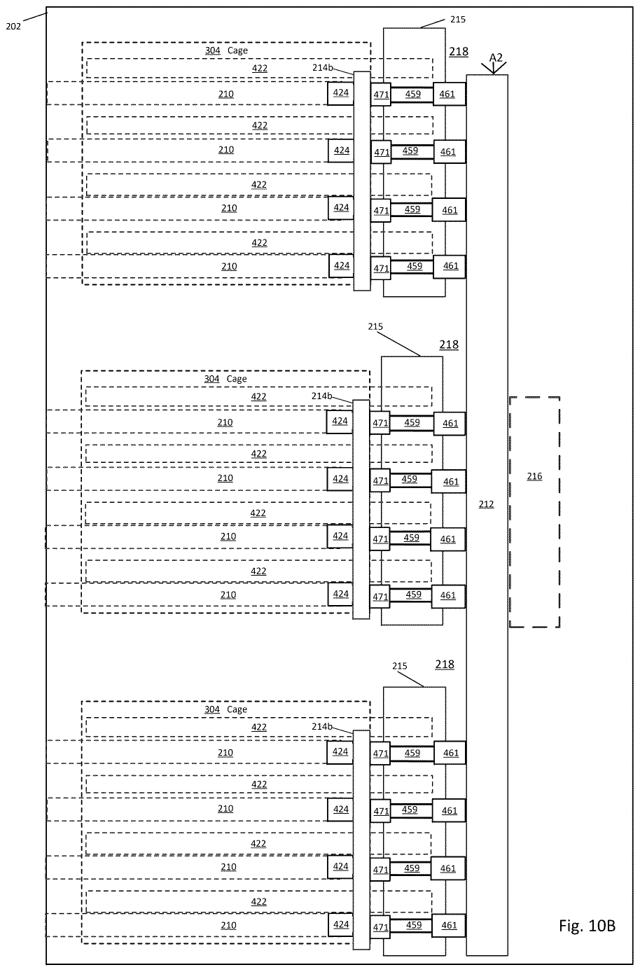

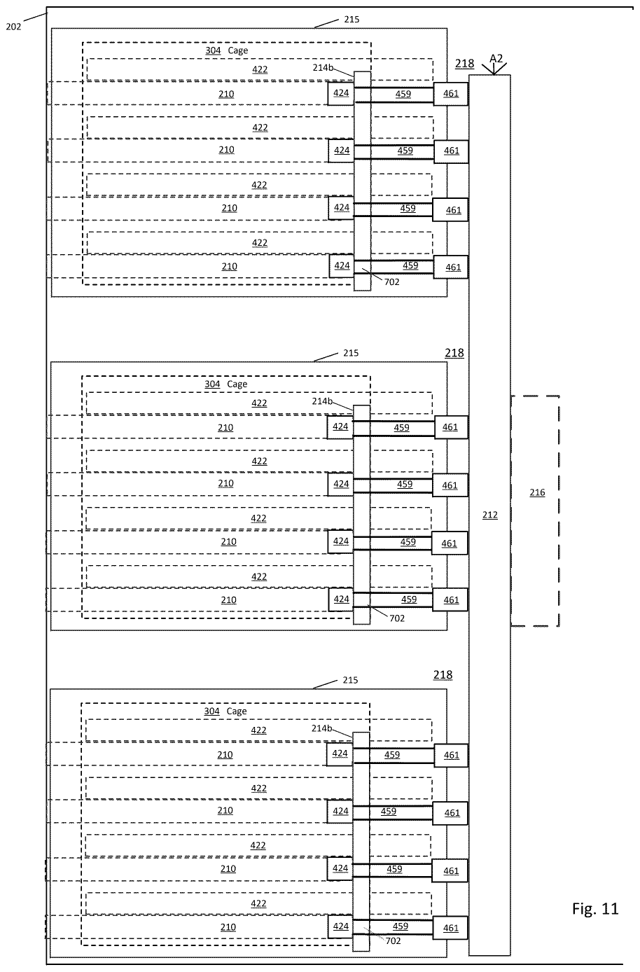

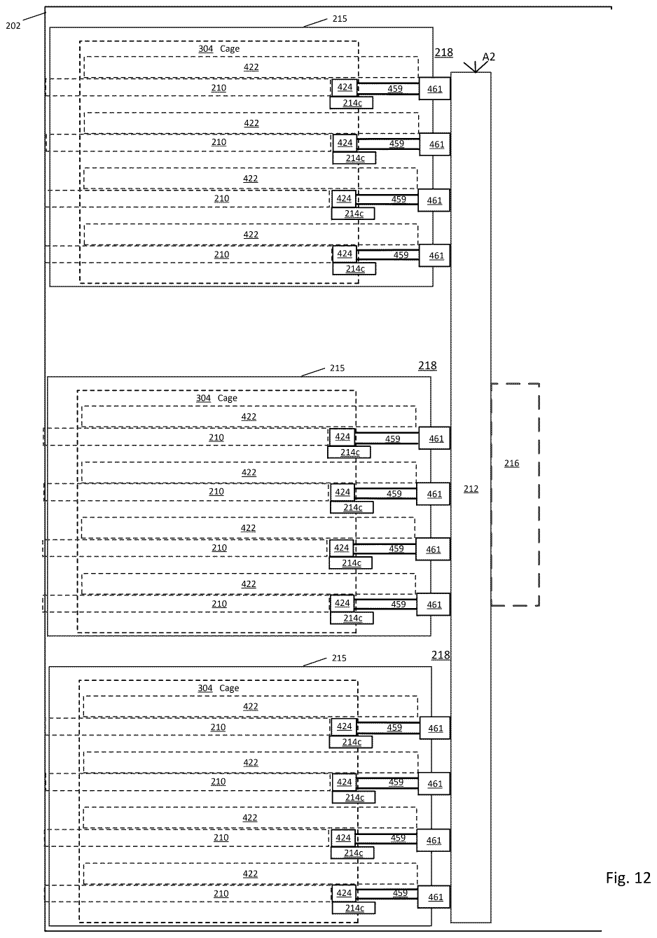

FIGS. 9A and 9B show alternative side views of the arrangement shown in FIG. 3, which are similar to the side views shown in FIGS. 4A and 4B, respectively. In FIGS. 9A and 9B, however, the two-piece connector (461/463) is replaced by a connector (461) having a unitary construction. In addition, FIGS. 10A, 10B, 11, and 12 show side views similar to those shown in FIGS. 6A, 6B, 7, and 8, respectively. In FIGS. 10A, 10B, 11, and 12, like FIGS. 9A and 9B, the two-piece connector 461/463 is replaced by a connector (461) having a unitary construction.

The foregoing disclosure provides illustration and description but is not intended to be exhaustive or to limit the implementations to the precise forms disclosed. Modifications may be made in light of the above disclosure or may be acquired from practice of the implementations.

Although particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

1. An apparatus, comprising:
a housing having a front panel, a top and a bottom;
a plurality of module cages, each of which being operable to receive a plurality of interface modules;
a plurality of sub-assembly enclosures, each of which including a respective one of the plurality of module cages;
a plurality of groups of first connectors, each of which being coupled to a respective one of a plurality of groups of interface modules, when the plurality of groups of interface modules is provided in the plurality of cages;
a plurality of groups of cable bundles;
a plurality of groups of second connectors;
an electrical connection extending from one of the plurality of first connector groups to one of the plurality of second connector groups, the electrical connection including one of the plurality of groups of cable bundles, and one of the plurality of second connector groups, one of the plurality of sub-assembly enclosures including at least a portion of the electrical connection;
a card, coupled to said one of the plurality of second connector groups, the card being provided vertically in the housing, such that the card is oriented at an angle relative to the front panel, the angle is in a range of −60° to 60°, the card including a processor.

2. An apparatus in accordance with claim 1, wherein the plurality of sub-assembly enclosures is arranged to be non-overlapping with the processor when viewed from the front panel.

3. An apparatus in accordance with claim 1, wherein each connector in each of the plurality of groups of second connectors is a two-piece connector.

4. An apparatus in accordance with claim 1, further including a plurality of groups of third connectors, each of which being coupled to a respective one of the groups of first connectors and a respective one of the plurality of groups cable bundles.

5. An apparatus in accordance with claim 1, wherein the card is a first card, the apparatus further including a plurality of second cards provided between a respective one of the plurality of groups of cable bundles and a respective one of the plurality of groups of first connectors.

6. An apparatus in accordance with claim 5, further including a plurality of groups of third connectors, each of which being provided between a respective one of the plurality of second cards and respective group of the plurality of cable bundles.

7. An apparatus in accordance with claim 6, wherein each of the plurality of sub-assembly enclosures includes a respective one of the plurality of module cages, a respective one of the plurality of second cards, and a respective one of the plurality groups of cable bundles.

8. An apparatus in accordance with claim 5, wherein each of the plurality of sub-assembly enclosures includes a respective one of the plurality groups of cable bundles, each of the plurality of module cages and each of the plurality of second cards being provided outside of each of the plurality of sub-assembly enclosures.

9. An apparatus in accordance with claim 5, further including a plurality of conductors embedded in each of the plurality of second cards, groups of the plurality of conductors in said each of the plurality of cards providing an electrical path between said respective one of the plurality of groups of cable bundles and said respective one of the plurality of groups of first connectors.

10. An apparatus in accordance with claim 5, wherein the angle is a first angle, each of the plurality of second cards is provided vertically in the housing, such that each of the plurality of second cards is oriented at a second angle relative to the front panel, the second angle is in a range from −60° to 60°.

11. An apparatus in accordance with claim 5, wherein each of the plurality of second cards is oriented parallel to the bottom of the housing.

12. An apparatus in accordance with claim 6, wherein each of the plurality of sub-assembly enclosures includes at least one of: a respective one of the plurality of the plurality of second cards, a respective one of the plurality of module cages, a respective one of the plurality of groups of first connectors, a respective one of the plurality of groups of cable bundles, a respective one of the plurality of groups of second connectors, and a respective one of the plurality of groups of third connectors.

13. An apparatus in accordance with claim 1, wherein said each of the plurality of sub-assembly enclosures includes a respective one of the plurality of module cages.

14. An apparatus in accordance with claim 1, wherein said each of the plurality of sub-assembly enclosures includes a respective one of the plurality of groups of first connectors.

15. An apparatus in accordance with claim 1, wherein said each of the plurality of sub-assembly enclosures includes a respective one of the plurality of groups of cable bundles.

16. An apparatus in accordance with claim 1, wherein said each of the plurality of sub-assembly enclosures includes a respective one of the plurality of groups of second connectors.

17. An apparatus in accordance with claim 1, wherein each of the plurality of first connectors, is operable to electrically connect to a respective one of a plurality of interface modules, when each of the plurality of interface modules is provided in a corresponding one of the plurality of module cages.

18. An apparatus in accordance with claim 11, wherein the plurality of interface modules being operable to transmit a first plurality of optical signals and receive a second plurality of optical signals.

19. An apparatus in accordance with claim 1, further including a plurality of heat transfer elements being operable to transfer heat away from the plurality of interface modules when each of the plurality of interface modules is provided in a respective one of the plurality of module cages.

20-22. (canceled)

23. An apparatus in accordance with claim 17, wherein the plurality of interface modules is operable to transmit a first plurality of electrical signals and receive a second plurality of electrical signals.

24-28. (canceled)

29. An apparatus in accordance with claim 1, wherein each of the plurality of interface modules is a pluggable module.

30-31. (canceled)

32. An apparatus, comprising:
a housing having a front panel, a top and a bottom;
a plurality of module cages;
a plurality of first connectors, each of which being operable to electrically connect to a respective one of a plurality of interface modules when the plurality of interface modules is provided in one of the plurality of module cages;
a plurality of first cards provided in the housing adjacent the front panel of the housing, such that each of the plurality of first cards is oriented at a first angle relative to the front panel, the first angle is in a range from −60° to 60°, the plurality of first connectors being provided on a first side of one of the plurality of first cards facing the front panel of the housing;
a plurality of second connectors provided on a second side of each of the plurality of second cards facing away from the front panel;
a plurality of two-piece connectors, each of which including a respective one of a plurality of third connectors and a respective one of a plurality of fourth connectors;
a plurality of cable bundles extending between the plurality of second connectors and the plurality of two-piece connectors;
a second card, the plurality of two-piece connectors being attached to the second card, the second card being provided vertically in the housing, such that the second card is oriented at a second angle relative to the front panel, the second angle is in a range of −60° to 60°, the second card including a processor; and
a plurality of sub-assembly enclosures, each of the plurality of sub-assembly enclosures including a group of the plurality of first connectors, a group of the plurality of second connectors, a group of the plurality of two-piece connectors, a corresponding one of the plurality of module cages, and a corresponding one of the plurality of first cards,
wherein the plurality of sub-assembly enclosures is arranged to be non-overlapping with the processor when viewed from the front panel.

33. An apparatus, comprising:
a housing having a front panel, a top and a bottom;
a plurality of module cages;
a plurality of first connectors, each of which being operable to electrically connect to a respective one of a plurality of interface modules when the plurality of interface modules is provided in one of the plurality of module cages;
a plurality of first cards provided in the housing adjacent the front panel of the housing, such that each of the plurality of first cards is oriented at a first angle relative to the front panel, the first angle is in a range from −60° to 60°, the plurality of first connectors being provided on a first side of one of the plurality of first cards, said one of the plurality of first cards having conductors extending from the first side to a second side of said one of the plurality of first cards;
a plurality of cable bundles;
a plurality of second connectors, each of which extending between the plurality of conductors of said one of the plurality of first cards and the plurality of second connectors;
a second card, the plurality of second connectors being provided on the second card, the second card being provided vertically in the housing, such that the second card is oriented at a third angle relative to the front panel, the third angle is in a range of −60° to 60°, the second card including a processor; and
a plurality of sub-assembly enclosures, the plurality of first connectors, the plurality of second connectors, the plurality of cable bundles, and a corresponding one of the plurality of first cards being provided in one of the plurality of sub-assembly enclosures,
wherein the plurality of sub-assembly enclosures is arranged to be non-overlapping with the processor when viewed from the front panel, and each of the plurality of second connectors being a two-piece connector.

34-36. (canceled)
